(19) United States
(12) Patent Application Publication
(10) Pub. No.: US 2022/0051879 A1
(43) Pub. Date: Feb. 17, 2022

(54) ELECTRODE ARRANGEMENT FOR A PLASMA SOURCE FOR PERFORMING PLASMA TREATMENTS

(71) Applicant: OERLIKON SURFACE SOLUTIONS AG, PFÄFFIKON, Pfäffikon (CH)

(72) Inventor: Jörg VETTER, Bergisch Gladbach (DE)

(73) Assignee: OERLIKON SURFACE SOLUTIONS AG, PFÄFFIKON, Pfäffikon (CH)

(21) Appl. No.: 17/415,999

(22) PCT Filed: Dec. 5, 2019
(86) PCT No.: PCT/EP2019/083897

§ 371 Date: Jun. 18, 2021

Related U.S. Application Data
(60) Provisional application No. 62/783,498, filed on Dec. 21, 2018.

(30) Foreign Application Priority Data
Feb. 26, 2019 (CH) 00235/19

(51) Int. Cl. H01J 37/32; C23C 14/32

(52) U.S. Cl. CPC H01J 37/32568; H01J 37/32055; H01J 37/34; C23C 14/325; H01J 37/32651

(57) ABSTRACT

In order to improve the etch depth and/or the etch homogeneity of a substrate, a plasma source with one or more evaporators and two or more electrodes according to the invention is proposed. The use of more than one electrode allows the use of different currents at the electrodes and a time-selective application of the currents, so that an improved control of the plasma generation is enabled.

### TECHNICAL FIELD

The present invention relates generally to a vacuum chamber having at least one plasma source, and in particular to a vacuum chamber having a plasma source for generating a plasma for performing plasma treatments on surfaces of substrates arranged within the plasma chamber, wherein a specific electrode arrangement allows an increased efficiency of the plasma treatment.

### BACKGROUND

On the one hand, electric glow discharge, which is formed by the passage of a current through a gas by applying a sufficiently high voltage between a cathode and an anode, such as argon or another noble gas at defined low pressures, can be used for plasma generation. On the other hand, the plasma generation of the gas or gas mixture in the form of a low-pressure plasma can be achieved by the interaction of high-energy electrons with gases, which are provided by an electron source and accelerated to defined energies by suitable electrodes. Such an electron source can be, for example, a cathodic vacuum arc evaporator consisting of a suitably shielded arc cathode and an arc anode receiving the arc electrons. For gas plasma generation, these arc electrons are removed with suitable electrodes and accelerated at high energy. The gas plasma generated in this way can be used for various plasma treatments of substrates. For example, inert gas ions (e.g., argon ions) generated in this way serve for an ion purification of the substrates. Chemical compounds excited in the plasma and, if necessary, decomposed, as well as atomized molecules of the gases and gas mixtures, can be used for thermochemical treatment of substrates or even for coating deposition. It is important to adjust the local plasma generation in a defined manner with regard to the treatment objectives with suitable electrodes in terms of form, arrangement and operating parameters. One objective is to design the electrodes in such a way that they do not protrude into the treatment room in a disturbing manner, that they can be applied with high power densities and that they are as easy to maintain as possible.

### DESCRIPTION OF THE PRESENT INVENTION

The invention relates to a vacuum chamber for performing a plasma treatment having a plasma treatment area which is enclosed by chamber walls, and a plasma source. Here, the plasma source comprises a cathode for cathodic vacuum arc evaporation with an arc anode which is connected to the chamber, wherein the cathode is arranged in the chamber on the chamber wall, a shield for shielding particles and metal ions which are emitted from the cathode, wherein the shield is provided on the chamber wall in such a way that it can be arranged in front of the cathode and an electrode arranged in the chamber and spaced from the cathode. Here, the electrode comprises a two-dimensional surface for collecting electrons emitted from the cathode. The two-dimensional surface has a first orthogonal extension and a second orthogonal extension to a surface normal, wherein the first orthogonal extension is perpendicular to the second orthogonal extension, and a length ratio of the first orthogonal extension to the second orthogonal extension is between 0.1 and 1. In particular, the electrode according to the invention can be anodically switched at least temporarily by means of a suitable current supply device.

In the following, some concepts are presented in simplified form as an introduction, which will be explained in more detail later.

The vacuum chamber according to the invention can be used in particular to enable and improve a locally adjustable treatment of substrates, and to control a plasma distribution of the vacuum chamber.

An electron source of the plasma source may be an arc cathode of an arc evaporator with a suitable shielding, which is connected to an arc power supply. The positive pole of the arc power supply can be connected to the chamber wall in a simple manner as an arc anode according to the invention. The arc electron-collecting electrode is connected to a positive pole of another power supply and is thus an electron-receiving electrode. This electrode is used to accelerate arc electrons in the direction of this electrode. These accelerated electrons excite a gas plasma and are collected on the substantially two-dimensional surface of the electrode. Typical industrial cathodic vacuum arc evaporators can be used as electron sources.

Depending on the operating mode, the power supply of the cathode and the power supply of the electrode can be switched and controlled. The electrode according to the invention can be operated both as an anode and as a coating source (cathodic vacuum arc evaporator, sputtering source; i.e., as a target). For this purpose, the power supply is negatively biased for an operation as a coating source and positively biased for an operation as an anode.

In front of the cathodic vacuum arc evaporator, which can be used as an electron source, a shield is preferably provided, which is designed in such a way that it can withstand the heat input from the vacuum arc evaporation. The dimensioning of one area of such a shield should be larger than the whole area of the cathodic vacuum arc evaporator, which comprises the surface to be evaporated, in order to avoid a vaporization of the substrates.

In an embodiment of the invention, one or more electron-collecting electrodes may be introduced into the treatment chamber in the form of uncooled electrodes. However, the use of uncooled electrodes may lead to a limitation of the power that can be applied to the electrodes. For this reason, cooled electrodes, for example water-cooled electrodes, are advantageously used. In this case, the part of the electrode forming the working surface is preferably cooled.

One or more typical power supplies (i.e., current sources) that can provide a voltage of up to 100 V and a current of up to 400 A can be used as the power supply for the electrodes. In this case, current densities between 0.1 and 5 A/cm² and power densities between 0.5 and 500 W/cm² can be achieved at the electrodes.

A total gas pressure in the range of 0.01 Pa to 10 Pa should be maintained in the chamber during the plasma treatment, preferably a gas pressure in the range of 0.1 Pa to 2 Pa. Typical gases are argon, hydrogen, nitrogen or hydrocarbon gases (e.g., C₂H₂, acetylene), which are used as pure gases or gas mixtures depending on the treatment objective.

The vacuum chamber according to the invention can comprise both a plurality of electrodes and a plurality of cathodes, in particular cathodic vacuum arc evaporators. Here, several cathodes, in particular cathodic vacuum arc evaporators, may have a single shield or several shields. Several cathodes, in particular cathodic vacuum arc evaporators, with the one shield can be advantageously arranged with at least one electrode in the vacuum chamber. In particular, the vacuum chamber may also comprise an equal number of electrodes and cathodes (in particular cathodic vacuum arc evaporators), more electrodes than cathodes (in particular cathodic vacuum arc evaporators), or more cathodes (in particular cathodic vacuum arc evaporators) than electrodes. Here, the electrodes and cathodes can be arranged at different locations in the vacuum chamber (walls, ceiling, floor). The plasma distribution in the vacuum chamber can be adjusted both via the arrangement and the number of electrodes and cathodes (in particular cathodic vacuum arc evaporators). In addition, for example, an improvement of the etching depth and/or the etching homogeneity on a substrate can be achieved in an ion etching process. The use of more than one electrode allows the use of different currents on the electrodes as well as a time selective application of the currents so that an improved control of plasma generation is enabled.

The electron current at the electrode can be adjusted by adjusting the electrode voltage. Low electrode voltages result in a low electron current and a low plasma activity.

A typical maximum electron current at the one or more electrodes should be selected at approximately 120% of the current of the cathodic vacuum arc evaporator (arc current). For example: If a cathodic vacuum arc evaporator is used as the electron source in a vacuum chamber containing argon at an argon pressure of 0.5 Pa, with the cathodic vacuum arc evaporator being operated at an arc current of 100 A, the total electrode current should be adjusted to approximately 120 A. This means that the current at the one electrode, or if more than one electrode is used, the sum of the individual currents at the individual electrodes, should be adjusted to 120 A.

When the plurality of electrodes are arranged along one (or more) chamber wall in such a way that they are distributed over the height of the vacuum chamber, each electrode can be operated on a separate power supply or on a specific group of power supplies so that the electrodes can be switched to operate them at a maximum or treatment-dependent optimized current or to operate them in parallel at a maximum current by applying different voltages to the different electrodes. Typical values of electrode voltage are in the range of 10 V-50 V and typical electrode currents are in the range of 10 A-200 A. To regulate the local plasma densities, these are operated with different currents. This can serve to set a homogeneous treatment objective, e.g., an ion cleaning.

When a mixture of an argon gas flow and a hydrogen gas flow is supplied to the chamber to generate a plasma in the chamber, which plasma is generated by one or more electron sources and one or more electrodes having two-dimensional surfaces for receiving electrons emitted from the cathode, a plasma generated in this way can be used as a plasma for ion cleaning the surfaces exposed to the plasma. If a nitrogen gas flow is additionally introduced into the chamber, a thermochemical heat treatment, colloquially designated as nitriding, can occur in the surfaces exposed to the plasma thus generated.

In addition, the present invention can be used for performing coating processes, for example, for depositing diamond-like carbon (DLC) coatings. In the case that a-C:H type DLC layer is to be deposited, a mixture of an acetylene (C₂H₂) gas flow and an argon gas flow should be supplied to the chamber.

Virtually any coating device designed to perform vacuum coating processes, such as PVD arc evaporation processes or PVD sputtering processes, including HiPIMS, or plasma enhanced chemical vapor deposition (PA-CVD) processes, can be adapted to perform plasma treatment processes according to the present invention.

In the arrangement according to the invention, the electron accelerating electrode is not spatially linear in the sense of a relationship between the length of the electrode and the cross sections, which are often rectangular or circular or elliptical. Substantially, two-dimensional electrodes are used. This means that the two-dimensional surface has the first orthogonal extension and the second orthogonal extension to the surface normal, wherein the first orthogonal extension is perpendicular to the second orthogonal extension. The length ratio of the first orthogonal extension to the second orthogonal extension is between 0.1 and 1. The two-dimensional surface can be circular, ellipsoidal but also rectangular or have other suitable shapes. If the two-dimensional surface is circular, the first orthogonal extension and the second orthogonal extension correspond in particular to the diameter of the two-dimensional surface. If the two-dimensional surface is rectangular, the first orthogonal extension corresponds to a first edge length and the second orthogonal extension corresponds to a second edge length of the two-dimensional surface. If the two-dimensional surface is ellipsoidal, the first orthogonal extension and the second orthogonal extension correspond in particular to distances from opposite vertices of the two-dimensional surface. The term two-dimensional also refers, among other things, to the fact that the electrons strike a substantially planar surface. However, the surface itself may have a certain structure due to its manufacture or use. This structuring can occur due to erosion of the electrode when used as a coating source. The electrode can be eroded due to erosion in such a way that it no longer has a smooth or regular structure/edge. Such structured and eroded electrodes are also considered substantially planar within the framework of the invention. The ratio between a maximum depth of the structuring and the smaller orthogonal extension (with respect to the first orthogonal extension or second orthogonal extension according to the invention) of the two-dimensional surface of the electrode is at most 0.4, in particular at most 0.3, especially at most 0.2. Thus, the maximum depth of the structuring should always be smaller than the smaller orthogonal extension.

In the simplest case, a circular electrode is operated, which preferably has an electrode diameter of 100 mm. In this case, the electrode can be attached to a wall of the vacuum chamber and can also be arranged at least partially in the chamber wall. If the electrode is at least partially arranged in the chamber wall, this has the distinct advantage that the electrode does not protrude significantly into the coating chamber. If, as described above, there are several two-dimensional electrodes, the electrodes may be attached to different chamber walls. For example, if two two-dimensional electrodes are installed, the two two-dimensional electrodes are preferably arranged on opposite chamber walls. Of course, there is also the possibility that several two-dimensional electrodes are arranged on adjacent and/or several two-dimensional electrodes on the same chamber wall. In this case, a first and a second electrode preferably have a distance of 20 to 400 mm, preferably 200 mm, when they are operated on a chamber wall one above the other or side by side.

The arrangement of the two-dimensional electrode on a chamber wall has in particular the following advantages compared to the state of the art with a linear electrode inside the vacuum chamber. The plasma treatment area inside the vacuum chamber, in particular in the center of the vacuum chamber, provides more free space. Due to this free space, a better use of the chamber can thus be achieved. For a better use of the chamber, the substrates to be treated can be better distributed within the vacuum chamber because there is more space to distribute the substrates to be treated due to the free space created in the chamber. In this way, a homogeneous plasma treatment of the substrate surfaces can also be made possible, in particular if the substrates to be treated can be arranged more uniformly in the chamber. It is a further advantage of the arrangement according to the invention that a simple cooling of these electrodes according to the invention is made possible. A two-dimensional surface such as is present in the electrodes according to the invention is, of course, much easier and more effective to cool than would be possible in the case of a linear electrode. The cooling of the electron-receiving surface can be direct (water flow) or indirect. Indirect is the clamping of a suitable electrode material on a cooling body.

In the case of the vacuum chamber according to the invention for performing a plasma treatment, among other things, a magnet system can also be used. The magnet system or the magnet systems can be used to adjust the distribution of the plasma in the vacuum chamber (chamber). In particular, a magnet system can be used to control the distribution of the plasma at the two-dimensional electrode.

The material of the cathode of the electron source on the basis of a cathodic vacuum arc evaporator (later also simply designated as evaporator), may preferably be titanium (Ti), zirconium (Zr) or aluminum (Al). The cathode can also be made of titanium alloys and/or zirconium alloys and/or aluminum as well as aluminum alloys. Of course, the material of the cathode can also be made of another suitable element, another suitable alloy or another suitable metal, which favors an adsorption of residual gases in the vacuum chamber (e.g., water, oxygen) caused by outgassing or leakage. Due to such characteristics of the cathode of the vacuum arc evaporator, which serves as an electron source, among other things, a better vacuum quality can also be achieved for performing the plasma processes. All possible target materials of cathodic vacuum arc evaporators known from the state of the art are suitable as electrode materials. In this case, among other things, carbon targets made of pure carbon or alloys such as copper-carbon alloys can be used as electrode materials. Steel, copper, copper alloys, aluminum, aluminum alloys, or conductive evaporator materials such as aluminum titanium, chromium, or vanadium are also suitable as electrode materials.

In an embodiment of the invention, the electrode according to the invention can be used as an anode (receiving arc electrons), and thus can be switched anodically, in particular temporarily. Furthermore, the second electrode can additionally be arranged in the vacuum chamber according to the invention, and a further third electrode spaced from the cathode can also be arranged. The second cathode and a fourth electrode spaced from the second cathode can also be provided in the vacuum chamber according to the invention, wherein the electrons emitted from the first cathode flow selectively toward the third electrode and the electrons emitted from the second cathode flow selectively toward the fourth electrode.

In practice, the second cathode can also be arranged in the vacuum chamber, wherein electrons emitted from the first cathode flow selectively to the first electrode and electrons emitted from the second cathode flow selectively to the second electrode. In an embodiment of the invention, the vacuum chamber comprises a first power supply connected to the electrode. Furthermore, the vacuum chamber according to the invention may comprise a second power supply connected to the second electrode.

The first power supply can be designed in such a way that a first current can be supplied to the first electrode, and the second power supply can be designed in such a way that a second current can be supplied to the second electrode. In this case, the first current may be different from the second current and the first electrode may be supplied with the first current during a first time interval and the second electrode may be supplied with the second current during a second time interval. The first time interval and the second time interval can overlap. Furthermore, the first current may be equal to the second current, and the first time interval may be different from the second time interval. As an alternative, the first current may be different from the second current and wherein the first time interval is equal to the second time interval.

### EXAMPLES AND PREFERRED EMBODIMENTS OF THE PRESENT INVENTION

According to an embodiment according to the invention, as represented for example in FIG. 2, a vacuum chamber for performing a plasma treatment preferably comprises: an area for performing plasma treatments, which area is enclosed by the chamber walls; a plasma source comprising at least one arc cathode of a cathodic vacuum arc evaporator arranged on a chamber wall within the chamber and connected to a power supply; wherein the positive pole of the power supply is connected to the chamber wall in a simple manner as the arc anode collecting the arc electrons. There is a shield in front of the cathodic vacuum arc evaporator. An electron-receiving electrode is attached to a chamber wall. This electrode will be connected to the positive pole of a further power supply so that arc electrons can be accelerated toward this electrode. This electrode generating the gas plasma has a substantially two-dimensional surface for collecting the electrons generated by the arc discharge. Preferably, the two-dimensional surface of the first electrode is in the range between 5 and 2000 cm², preferably between 25 and 320 cm².

In the case of another embodiment according to the invention, a vacuum chamber for performing a plasma treatment comprises as follows: an area for performing plasma treatments, wherein the area is enclosed by the chamber walls; a plasma source comprising at least one cathode, arranged on a chamber wall within the chamber and connected to a power supply; a first electrode arranged within the chamber on one of the chamber walls spaced from the at least one cathode; a second electrode arranged within the chamber on one of the further chamber walls spaced from the at least one cathode; and a first power supply, wherein the first power supply is connected to the first electrode or to the first and second electrodes, and wherein each of the two electrodes designated as first and second electrodes is operated as an anode and comprises in each case a two-dimensional surface for collecting the electrons emitted from the at least first cathode. The two-dimensional surface for collecting the electrons emitted from the cathode is in the range between 5 and 2000 cm² for both the first electrode and the second electrode, preferably between 25 and 320 cm².

According to a further embodiment, a plasma source comprises as follows: a vacuum-tight chamber: a first cathode arranged in the chamber; a second cathode arranged in the chamber; a first electrode arranged in the chamber spaced from the first cathode; and a second electrode arranged in the chamber spaced from the second cathode, wherein the electrons emitted from the first cathode selectively flow towards the first electrode and the electrons emitted from the second cathode selectively flow towards the second electrode.

### BRIEF DESCRIPTION OF THE DRAWINGS

The same reference signs designate the same elements, features and structures in all drawings and throughout the description. The relative size and representation of these elements may, for reasons of clarity, illustration or expediency, be out of scale.

FIG. 1 shows an example of a known vacuum chamber for performing a plasma treatment.

FIG. 2 shows a schematic representation of a vacuum chamber according to the invention for performing a plasma treatment with an electrode according to a first embodiment.

FIG. 2a shows a schematic representation of a vacuum chamber according to the invention for performing a plasma treatment with a rectangular electrode according to a further embodiment.

FIG. 2b shows a schematic representation of a vacuum chamber according to the invention for performing a plasma treatment with an electrode with a switch between electrode and power supply according to a further embodiment.

FIG. 2c shows a schematic representation of a vacuum chamber according to the invention for performing a plasma treatment with an electrode with a switch for reversing the polarity of a power supply according to a further embodiment.

FIG. 3 shows a schematic representation of a vacuum chamber according to the invention for performing a plasma treatment with two electrodes according to the invention with a power supply according to another embodiment.

FIG. 4 shows a schematic representation of a vacuum chamber according to the invention for performing a plasma treatment with two electrodes according to the invention with two power supplies according to a further embodiment.

FIG. 5 shows a schematic representation of a vacuum chamber according to the invention for performing a plasma treatment with an electrode according to the invention and two cathodes according to a further embodiment.

FIG. 6 shows a schematic representation of a vacuum chamber according to the invention for performing a plasma treatment with two electrodes according to the invention and two cathodes according to a further embodiment.

FIG. 7 shows a schematic representation of a vacuum chamber according to the invention for performing a plasma treatment with two electrodes according to the invention and two cathodes according to a further embodiment.

FIG. 8 shows a schematic representation of a vacuum chamber according to the invention for performing a plasma treatment with three electrodes according to the invention and three cathodes according to a further embodiment.

FIG. 8a shows a schematic representation of a vacuum chamber according to the invention for performing a plasma treatment with three electrodes according to the invention and three cathodes according to a further embodiment.

FIG. 9 shows a schematic representation of a vacuum chamber according to the invention for performing a plasma treatment with three electrodes according to the invention, on different chamber walls according to another embodiment.

FIG. 9a shows a schematic representation of a vacuum chamber according to the invention for performing a plasma treatment with three electrodes according to the invention, on different chamber parts according to another embodiment.

### DETAILED DESCRIPTION

In the drawings, examples are described that comprise one or more embodiments. In this regard, the invention is not limited to the examples described. For example, one or more features of an embodiment can also be realized in another embodiment or even provided in another type of device.

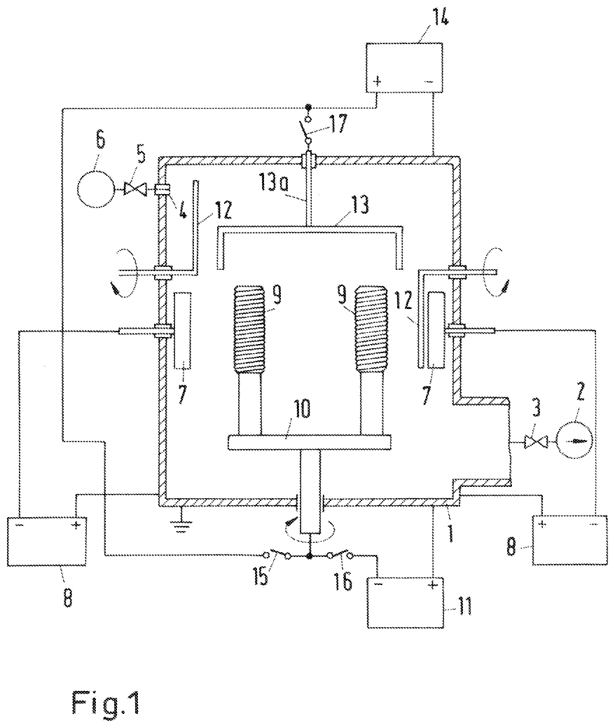

Before performing a coating process, such as a coating by means of physical vapor deposition (PVD) or a diamond-like carbon coating, an arc assisted glow discharge process (also known as ion etching process) can be performed on one or more substrates. In this case, the ion etching process is used to prepare or condition the surfaces, i.e., the substrate surfaces are heated and etched by means of an ion bombardment. This conditioning improves the bonding between the substrate and the coating. In FIG. 1, a conventional ion etching system is represented. The system of FIG. 1 comprises a vacuum chamber 1 with evaporators 7 (in the following, the term evaporator short for arc cathode of a cathodic vacuum arc evaporator) arranged on opposite sides of the chamber 1. The evaporators 7 are connected to direct current sources 8 and can be operated at voltages of 40 V and currents up to 300 A. Shutters or shields 12 are connected to the walls of the chamber 1 and are rotatably arranged in such a way that the shutters 12 can be rotated such that the corresponding electrode 7 is either shielded or unshielded. A linear electrode 13 is connected to the chamber and equally spaced from the evaporators 7. The linear electrode 13 can be connected to the current sources 11, 14 via switches 15, 16, 17 and has an equal voltage along the electrode 3 in the operating state. The current sources 11, 14 are additionally connected to the wall of the chamber 1 and can optionally be connected to a rotatable substrate holder 10 via the switches 15, 16. Gas, such as argon, can be admitted to the chamber 1 from a gas source 6 through the inlet 4 via the valve 5. When an arc discharge is ignited, electrons are generated by the evaporator 7 and accelerated toward the linear electrode 13. The electrons excite the argon gas atoms and thus generate partially ionized argon atoms, which are deposited on a surface of a substrate 9 to prepare it for the coating. This system can be adjusted only by means of the direct current sources 8, 11, 14 and the rotating substrate holder 10. Thus, the system is characterized by limited ionization, limited adjustability of plasma activation by the linear electrode 13, and limited adjustability of homogeneity in the chamber 1.

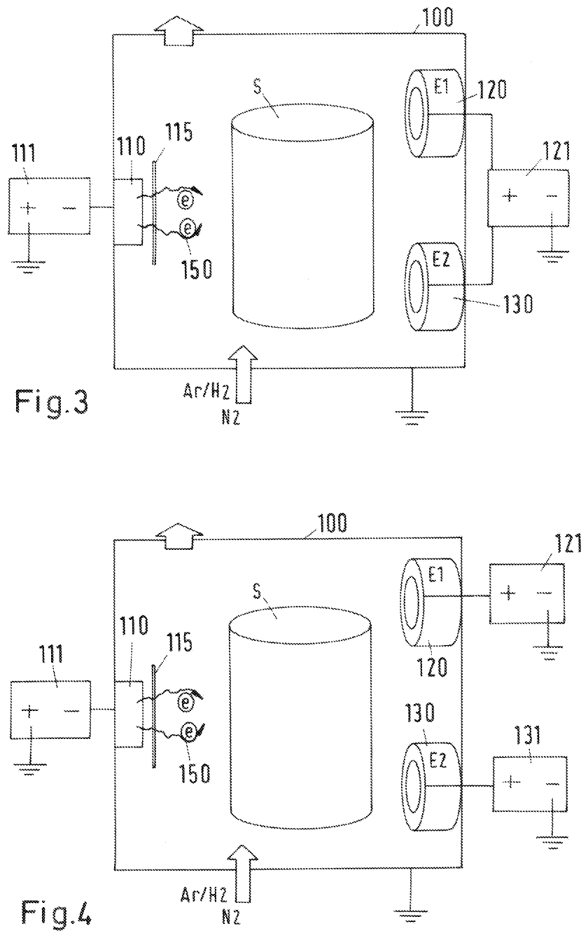

Now, embodiments of plasma sources are schematically represented in FIGS. 3, 4 and 9. In order to be able to better control the flow of electrons in the chamber 100 (i.e., a vacuum chamber according to the invention, hereinafter referred to as chamber), a plurality of electrodes 120, 130, 140 according to the invention having a two-dimensional surface for collecting the electrons emitted from a cathode is provided, which can be arranged in the chamber, unlike in the case of the device comprising a linear electrode according to FIG. 1. A very important advantage of this arrangement is the possibility to position the electrodes on one or more walls of the chamber, whereby an improvement of a distribution of the substrates to be treated with plasma in the chamber is made possible. As a result, the area in the chamber for plasma treatment can be better utilized, resulting in higher efficiency. For example, a vacuum-tight chamber 100 is schematically represented in FIG. 3 or 4. An evaporator 110 is provided in the chamber 100 and can be arranged directly in the wall or on the wall of the chamber 110. The evaporator 110 can comprise one or more metals, such as titanium and/or any other metal intended for evaporation. A negative pole of the power supply or power source is connected to the evaporator 110, thus connecting the evaporator 110 in the form of a cathode. For example, when the evaporator 110 is ignited by means of a trigger unit, arc electrons are emitted which are accelerated by means of the electrode according to the invention and collide with one or more gases such as argon (Ar), neon (Ne) or any other suitable gas or gases which have been admitted into the chamber 110, and thus create a plasma. Then, the ions of the plasma bombard the surfaces of the one or more substrates (not shown here) that are provided in the chamber 100 to prepare their surfaces for a subsequent coating process, for example, by cleaning or etching. One or more shields 115 are movably provided in the chamber 100 so that the shield 115 can be optionally positioned between the evaporator 110 and the substrate. Thus, the shield 115 may be either rotated or otherwise moved in front of the evaporator before the ignition of the arc process to protect the substrates from contamination by the evaporator 110 during this process. If the arc is not present, the shield can be moved to another suitable position.

According to FIGS. 3 and 4, two electrodes, a first electrode 120 and a second electrode 130 are provided in the chamber 100. The first and second electrodes 120, 130 are connected to a positive pole of the at least one power supply or current source, and thereby connect the first and second electrodes 120, 130 as first and second anodes. For example, as represented in FIG. 3, a common power supply 121 can be connected to the first electrode 120 and the second electrode 130. In this arrangement, an equal voltage can be applied to the first electrode 120 and the second electrode 130. This voltage can be applied to both electrodes 120, 130 at the same time and for the same duration. As an alternative, according to FIG. 4, a first power supply 121 may supply a current to the first electrode 120 during a first time interval and a second power supply 131 may supply a current to the second electrode 130 during a second time interval. The first and the second time intervals may be separate or overlapping, as desired. In another embodiment, the first electrode 120 may be connected to a first power supply 121 and the second electrode 130 may be connected to a second power supply 131. Thus, the first power supply 121 can supply the first electrode 120 with a first current and the second power supply 131 can supply the second electrode 130 with a second current. By using different currents and/or different time intervals, the plasma generated in the system can be influenced, controlled or even homogenized.

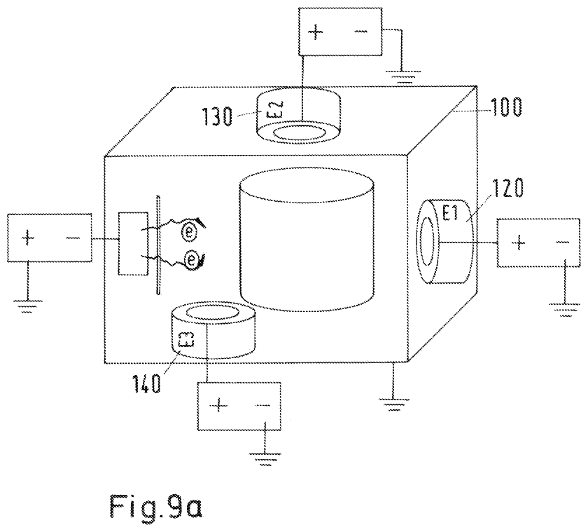

As represented in FIGS. 3 and 4, the electrons emitted from the evaporator 110 flow to the positions of the first and second electrodes 120, 130. By a suitable positioning of the individual first electrode 120 and second electrode 130 at the desired locations, a better control of the plasma flow in the chamber 100 is possible and consequently an improved control of the ion bombardment and etching of the substrate S. FIG. 9 illustrates an embodiment in which three individual electrodes, a first electrode 120, a second electrode 130, and a third electrode 140 are provided. Thus, a corresponding first, second, and third electron path 160 results, which in each case is directed toward the first, second, and third electrodes 120, 130, 140. In the schematic drawings according to FIGS. 3 and 4, the electrodes 120, 130 are arranged opposite the evaporator 110. However, in the schematic drawing according to FIG. 9, the electrodes 120, 130, 140 are arranged on different chamber parts. However, it is understood that any suitable positioning of the first, second or optionally third electrode is possible to influence the electron flow in such a way that an improved plasma activation and homogeneity in the chamber can be achieved. Accordingly, any number of electrodes in the chamber is possible to guide the electron flow to a desired path. The evaporator 110 according to FIGS. 3, 4 and 9 can be used with an applied current of 100 A; however, any other suitable current may of course be used.

FIG. 6 shows a further embodiment of a plasma source in which several evaporators are provided. A chamber 200 comprises a first evaporator 210 and a second evaporator 220 that are connected as cathodes. The first and second evaporator 210, 220 can be provided in the wall of the chamber 200 or otherwise on the chamber 200. As an alternative, the first or second evaporator 210, 220 can be arranged on a suitable structure of the chamber 200 or in the chamber 200. A rotatable or otherwise movable shield 230 is provided near the first and second evaporator 210, 220. The shield 230 may have a size that is sufficient to shield both evaporators 210, 220. As an alternative, the chamber 200 can comprise a first and second shield that are associated in each case with the first evaporator 110 and the second evaporator 220. Furthermore, a first electrode 240 and a second electrode 250 are provided in the chamber 200, both of which are connected as anode. As represented by the electron paths 260, the electrons emitted from the first evaporator 210 flow toward the first electrode 240 and electrons emitted from the second evaporator 220 flow toward the second electrode 250. It is understood that any desired number of evaporators can be used with any desired number of individual electrodes. Thus, for example, the system of FIG. 6 can comprise two evaporators and four individual electrodes so that electrons flow from the first evaporator 210 to two individual electrodes and the electrons flow from the second evaporator to two other individual electrodes.

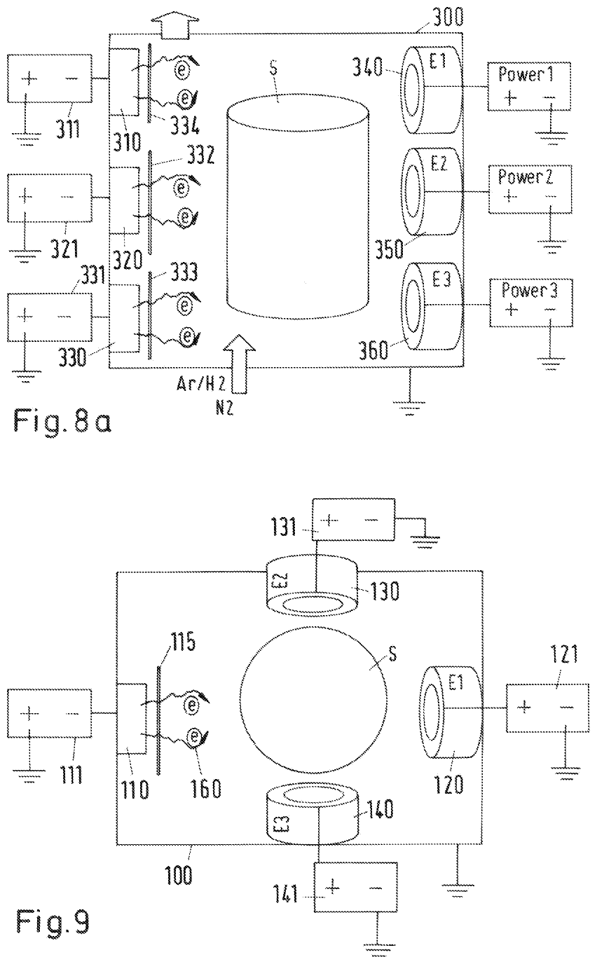

The embodiment according to FIG. 8 can be used in large systems in particular. Several plasma sources may be provided in the chamber by arranging evaporators 311, 321, 331 and electrodes 340, 350, 360 along the height of the chamber, this means along the height of the plasma treatment area, the plasma source in each case comprising at least one evaporator and one, two or more individual electrodes. Here, each electrode can be supplied by its own power supply or even a switchable power supply can be used by several electrodes simultaneously.

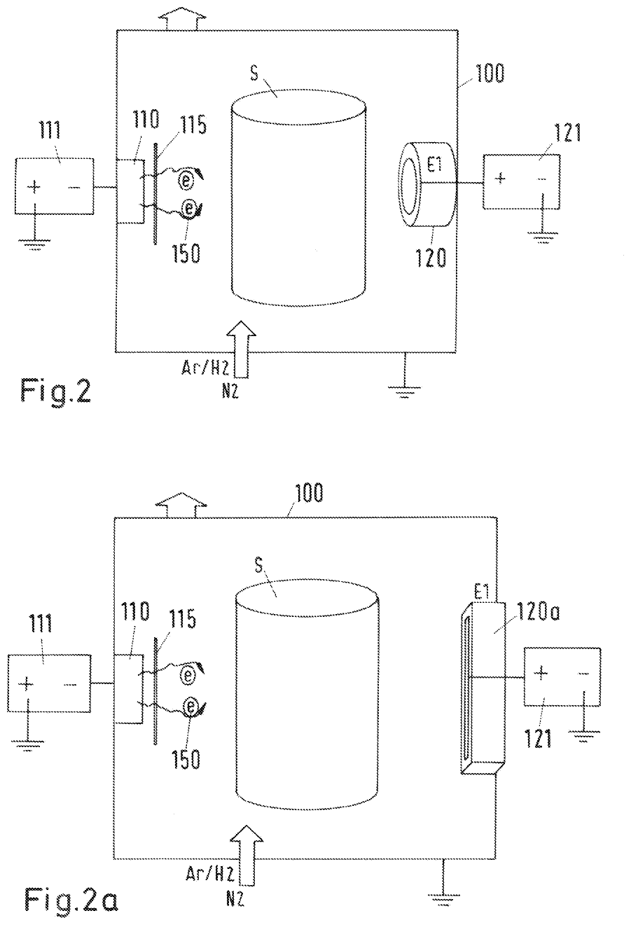

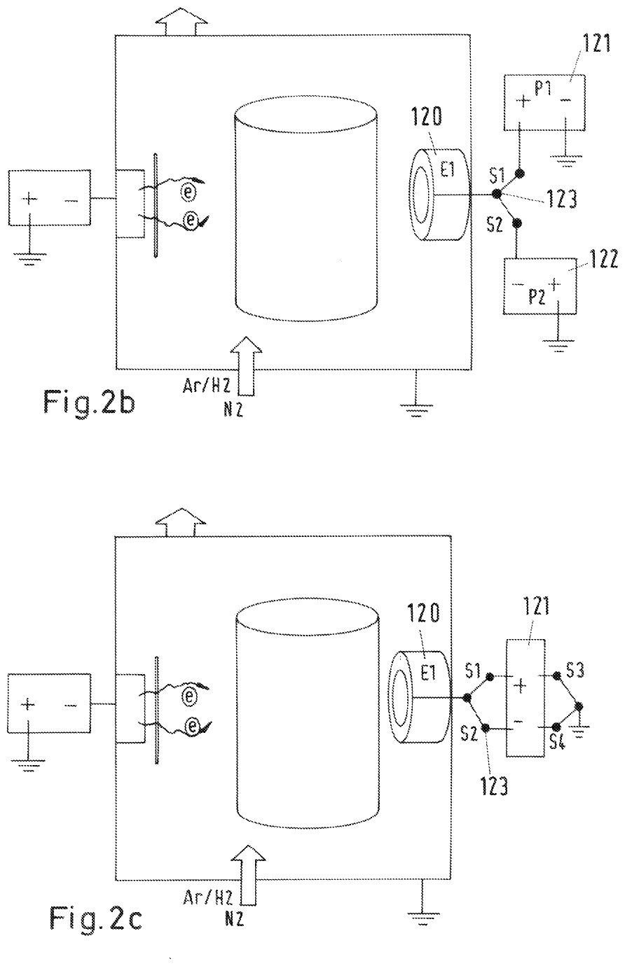

The embodiment according to FIG. 2 shows a schematically represented vacuum-tight chamber 100, an evaporator 110 which is provided in the chamber 100 and which can be arranged directly on the wall of the chamber 100. Furthermore, a power supply 111 is provided, which has a negative pole. This negative pole of the power supply 111 or the power source 111 is connected to the evaporator 110. Thus, in the present embodiment, the evaporator 110 is a cathode 110. As represented, the evaporator 110 emits arc electrons, which are first partially extracted and accelerated by the electrode according to the invention, and thus exciting the working gas argon (Ar) (often also neon (Ne) or any other suitable gas or mixture of gases) and consequently creating a plasma. For this purpose, a positive accelerating voltage is applied to the electrode 120, which enables an electrode current to the electrode. The control of the electrode can be achieved generally by the voltage or the current, or it can be achieved by the energy consisting of the product of voltage and current. The ions of the plasma then hit on a surface of the substrate 5, which is preferably provided in a centered manner in the chamber 100, in order to prepare and activate its surfaces, for example by cleaning or etching, for a subsequent coating process. Furthermore, a shield 115 is movably arranged in the chamber 100 of FIG. 2, so that the shield 115 can be optionally positioned between the evaporator 110 and the substrate S. Thus, before the ignition of the arc process, the shield 115 may be either rotated or otherwise moved in front of the evaporator 110 to protect the substrate S from contamination by the evaporator 110 during this process. If the arc is not present, the shield can be moved to another suitable position.

According to FIG. 2, a single electrode 120 is provided. The electrode 120 is connected to a positive pole of a power supply 121, and consequently the electrode 120 is an anode 120. By using different currents and/or different time intervals at the current source 121 of the anode 120, the plasma that can be generated in the system can be influenced.

As represented in FIG. 2, the electrons emitted from the evaporator 110 are guided to the position of the electrodes/anodes 120 along a first and a second electron path 150. Thus, in turn, a plasma that can be generated in the chamber 100 can be accelerated in the same direction. Due to a suitable positioning of the first electrode 120 at a desired position, a better/easier control of the plasma flow in the chamber 100 is possible and consequently an improved control of the ion bombardment and etching of the substrate.

The embodiment according to FIG. 2a shows a schematically represented vacuum-tight chamber 100 with an analogous structure as the chamber 100 according to the embodiment according to FIG. 2. However, the two-dimensional surface for collecting the electrons emitted from the cathode of the first electrode 120a according to FIG. 2a is rectangular, whereas the two-dimensional surface of the first electrode 120 according to FIG. 2 is circular. In this case, the two-dimensional surface for collecting electrons emitted from the evaporator has a first orthogonal extension and a second orthogonal extension to a surface normal, wherein the first orthogonal extension is perpendicular to the second orthogonal extension, and a length ratio of the first orthogonal extension to the second orthogonal extension is between 0.1 and 1. In the case of the circular electrode 120, the first orthogonal extension and the second orthogonal extension correspond in particular to the diameter of the two-dimensional surface. In the case of the rectangular electrode 120a, the first orthogonal extension corresponds to a first edge length and the second orthogonal extension corresponds to a second edge length of the two-dimensional surface.

The embodiment according to FIG. 2b shows a schematically represented vacuum-tight chamber 100 with an analogous structure as the chamber 100 according to the embodiment according to FIG. 2. However, the embodiment according to FIG. 2b comprises a switch device 123 coupled between the first electrode 120 and the power supplies 121, 122. The power supply 121 is arranged with the positive pole on switch S1 of the switch device 123 and the power supply 122 is arranged with the negative pole on switch S2 of the switch device 123. When switch S1 is closed and switch S2 is open, the electrode 120 can be used as a plasma electrode according to the invention (i.e., also as an anode). When switch S1 is open and switch S2 is closed, the electrode 120 can be used for (arc) coating processes or sputtering processes (i.e. target).

The embodiment according to FIG. 2c shows a schematically represented vacuum-tight chamber 100 with an analogous structure as the chamber 100 according to the embodiment according to FIG. 2. However, the embodiment according to FIG. 2c comprises a switch device 123 coupled between the first electrode 120 and the power supply 121. The power supply 121 is arranged with the positive pole on switch S1 of the switch device 123 and with the negative pole on switch S2 of the switch device 123. Furthermore, the positive pole of the power supply 121 is connected to a ground via the one switch S3 and the negative pole of the power supply 121 is connected to the ground via the one switch S4. When switch S1 is closed, switch S2 is open, switch S3 is open, and switch S4 is closed, the electrode 120 can be used as a plasma electrode according to the invention. When switch S1 is open and switch S2 is closed, switch S3 is closed, and switch S4 is open, the electrode 120 can be used for (arc) coating processes or sputtering processes.

The embodiment according to FIG. 3 shows the schematically represented vacuum-tight chamber 100. In this case, the first electrode 120 and the second electrode 130 are connected to a positive pole of the same power supply 121 or the same power source 121. As a consequence, the first electrode 120 and the second electrode 130 are a first anode 120 and a second anode 130. By using different currents and/or different time intervals at the current source 121 of the anodes 120 and 130, the plasma that can be generated in the system can be influenced.

Since the common power supply is connected to the first electrode 120 and the second electrode 130, an equal voltage can be applied to the first electrode 120 and the second electrode 130 with this arrangement. This current can be applied to both electrodes 120, 130 at the same time and for the same duration.

The embodiment according to FIG. 4 shows the schematically represented vacuum-tight chamber 100. In the embodiment according to FIG. 4, a first power supply 121 is arranged at the first electrode 120 and a second power supply 131 is arranged at the second electrode 130. In this case, the plasma that can be generated in the system can be influenced by using different currents and/or different time intervals at the first power supply 121 and the second power supply 131, in particular as the first power supply can supply the first electrode 120 with a first current and the second power supply can supply the second electrode 130 with a second current. Here, the first and second currents can be adjusted independently of each other, so that the distribution of the plasma can be shaped by the first and the second current. Here, the first power supply 121 may supply the first electrode 120 with the first current during a first time interval and the second power supply 131 may supply the second electrode 130 with the second current during a second time interval. The first and the second time intervals may be separate or overlapping, as desired.

In the embodiments according to FIGS. 2 to 4, a single evaporator 110 in each case is present, whereby a plasma arc is generated with at least one anode 120, 130.

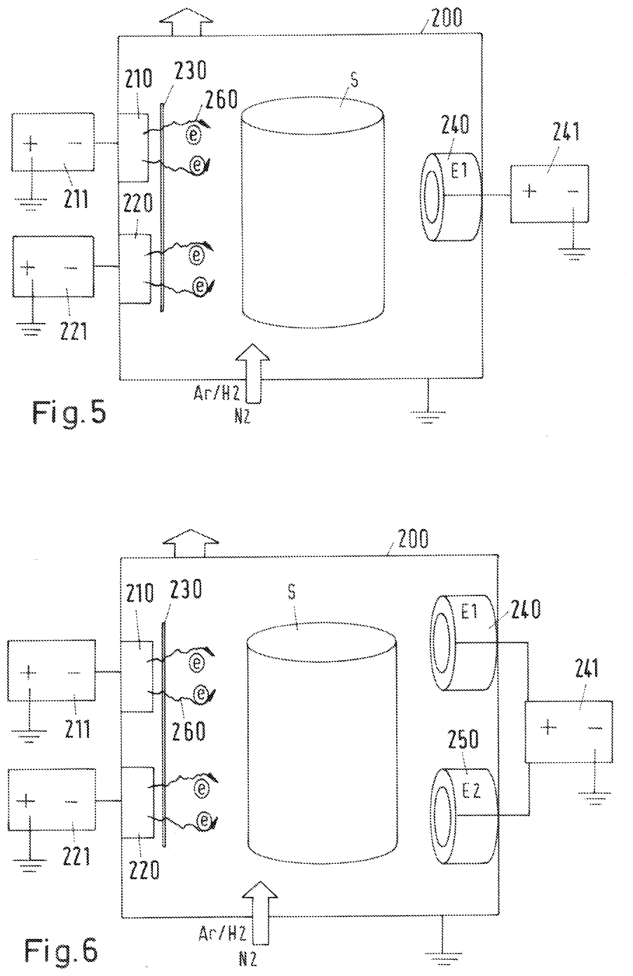

FIG. 5 shows a further embodiment of a chamber 200 in which several evaporators are provided. The chamber 200 comprises a first evaporator 210 and a second evaporator 220 that are connected as cathodes, i.e., connected to a negative pole of a first power supply 211 and a second power supply 221. The first and second evaporators 210, 220 are provided on the wall of the chamber 200. As an alternative, the first or second evaporator 210, 220 may also be arranged on a suitable structure of the wall of the chamber 200 or in the chamber 200. A rotatable or otherwise movable shield 230 is provided near the first and second evaporator 210, 220. The shield 230 may have a size that is sufficient to shield both evaporators 210, 220. As an alternative, the chamber 200 may comprise a first and a second shield, which is associated with the first evaporator and the second evaporator 210, 220, respectively (not shown here). Furthermore, a first electrode 240 is provided in the chamber 200, which is connected as an anode, i.e., connected to the positive pole of a first current source 241. As represented by the electron paths 260, the electrons emitted from the first evaporator 210 and the electrons emitted from the second evaporator 220 flow toward the first electrode 240. It is understood that any desired number of evaporators may be used with any desired number of individual electrodes, so that the system may comprise a suitable number of evaporators and a suitable number of electrodes.

The embodiment according to FIG. 6 shows a schematically represented vacuum-tight chamber 200 with an analogous structure as the chamber 200 according to the embodiment according to FIG. 5. However, the embodiment according to FIG. 6 differs from FIG. 5 in that a first electrode 240 and a second electrode 250 are present. In this case, the first electrode 240 and the second electrode 250 are connected to a positive pole of the same power supply 241 or the same power source 241. As a consequence, the first electrode 240 and the second electrode 250 are switched as a first anode 240 and a second anode 250.

Since the common power supply is connected to the first electrode 240 and the second electrode 250, an equal current can be applied to the first electrode 240 and the second electrode 250 in this arrangement. This current can be applied to both electrodes 240, 250 at the same time and for the same duration.

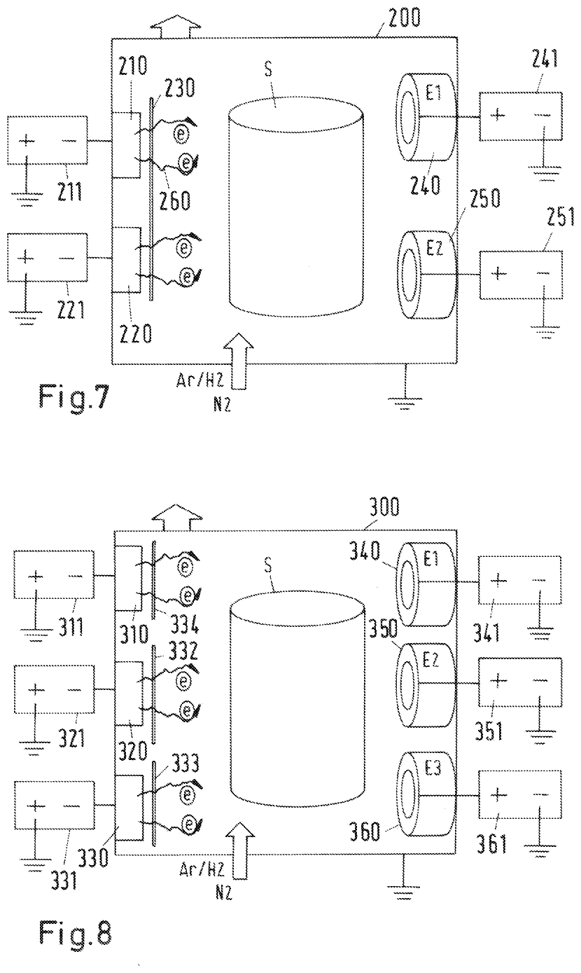

The embodiment according to FIG. 7 shows a schematically represented vacuum-tight chamber 200 with an analogous structure as the chamber 200 according to the embodiment according to FIG. 6. However, the embodiment according to FIG. 7 differs from FIG. 6 in that a first power supply 241 is arranged at the first electrode 240 and a second power supply 251 is arranged at the second electrode 250. Here, the plasma that can be generated in the system can be influenced by using different currents and I or different time intervals at the first power supply 241 and the second power supply 251, in particular as the first power supply can supply the first electrode 240 with a first current and the second power supply can supply the second electrode 250 with a second current. The first and second currents can be independently adjustable in this case, so that the distribution of the plasma can be shaped by the first and second current. Here, the first power supply 241 may supply the first electrode 240 with the first current during a first time interval and the second power supply 251 may supply the second electrode 250 with the second current during a second time interval. The first and the second time intervals may be separate or overlapping, as desired.

In the embodiments according to FIGS. 5 to 7, two evaporators 210, 220 in each case are present with at least one anode 240, 250.

FIG. 8 shows a further embodiment of the chamber 300, in which several evaporators are provided. The chamber 300 comprises a first evaporator 310, a second evaporator 320, and a third evaporator 330 that are connected as cathodes, i.e., connected to a negative pole of a first power supply 311, a second power supply 321, and a third power supply 331. The first, second, and third evaporators 310, 320, and 330 are provided on the same wall of the chamber 300. As an alternative, the first, second, and third evaporators 310, 320, and 330 may also be arranged on a suitable structure of the wall of the chamber 300 or in the chamber 300. Furthermore, first, second, and third evaporators 310, 320, and 330 may be arranged on different walls, respectively first and third evaporators 310 and 330 on one wall and the second evaporator 320 on another wall. Three rotatable or otherwise movable shields 334, 332, and 333 are in each case provided near the first, second, and third evaporator 310, 320, and 330. As an alternative, the chamber 300 may comprise a shield which has a size that is sufficient to shield all of the evaporators 310, 320, 330. Furthermore, a first electrode 340, a second electrode 350 and a third electrode 360 are provided in the chamber 300, which are connected as anodes 340, 350, 360, i.e., connected in each case with the positive pole to a first power supply 341, a second power supply 351 and a third power supply 361. As represented by the electron paths, the electrons emitted from the first evaporator 310, the electrons emitted from the second evaporator 320, and the electrons emitted from the third evaporator 330 flow toward the three anodes 340, 350, 360.

In the schematic drawing according to FIG. 8, the electrodes 340, 350, 360 are arranged opposite the evaporators 310, 320, 330. However, it is understood that any suitable positioning of the first, second and third electrode is possible to influence the electron flow in such a way that an improved plasma activation and homogeneity in the chamber can be achieved. Accordingly, any number of electrodes in the chamber is possible to direct the electron flow to a desired path. The current applied to the evaporators 310, 320, 330 can be 100 A, but of course any other suitable current can be used.

Thus, in the embodiment according to FIG. 8, three evaporators 310, 320 and 330 are present with three anodes 340, 350 and 360.

FIG. 8 a shows a further embodiment of a chamber 300, with an analogous structure to the chamber in FIG. 8, but the power supplies of the first electrode 340, the second electrode 350, and the third electrode 360 are operated at different energies. Among other things, by using the different energies, the homogeneity of a plasma can be improved, as well the distribution of a plasma can also be better controlled by adjusting the energies at the respective power supplies accordingly.

The embodiment according to FIG. 9 shows a schematically represented vacuum-tight chamber 100 with an analogous structure as the chamber 100 according to the embodiment according to FIG. 2. However, the embodiment according to FIG. 9 differs from FIG. 2 in that a first electrode 120, a second electrode 130 and a third electrode 140 are present and in that a first power supply 121 is arranged at the first electrode 120, a second power supply 131 at the second electrode 130 and a third power supply 141 at the third electrode 140. In this case, the plasma that can be generated in the system can be influenced by using different energies and/or different time intervals at the first power supply 121, the second power supply 131, and the third power supply 141, in particular as the first power supply 121 supplies the first electrode 120 with a first energy and the second power supply 131 can supply the second electrode 130 with a second energy and the third power supply 141 can supply the third electrode 140 with a third energy. In this case, the first, second, and third energies can be independently adjustable from each other, so that the distribution of the plasma can be shaped by the first, the second, and the third energies.

FIG. 9 illustrates an embodiment in which three individual electrodes, a first electrode 120, a second electrode 130, and a third electrode 140 are thus provided. Thus, a corresponding first, second and third electron path 160 results, which is directed towards the first, second and third electrode 120, 130, 140 in each case. In the schematic drawings according to FIG. 13, the electrodes 120, 130, 140 are arranged opposite the evaporator 110. However, it is understood that any suitable positioning of the first, second or optionally third electrode is possible to influence the electron flow in such a way that an improved plasma activation and homogeneity in the chamber can be achieved. Accordingly, any number of electrodes in the chamber is possible to direct the electron flow to a desired path.

As can be recognized from FIGS. 4 to 8, the substrate S can be biased negatively as well as positively, whereby the positive bias must be smaller than that of the electrode, as otherwise all electrons will flow to the substrate. Of course, an appropriately biased substrate is also suitable for additional plasma control. Furthermore, a working gas and a process gas are supplied to the chamber 100, 200 in the operating state. Here, the working gas is preferably argon (Ar) and hydrogen (H₂), and the process gas is preferably nitrogen (N₂).

The embodiment according to FIG. 9a shows a schematically represented vacuum-tight chamber 100 with an analogous structure as the chamber 100 according to the embodiment according to FIG. 9. However, in the embodiment according to FIG. 9a, the electrodes 120, 130, 140 are not only arranged on chamber walls of the chamber 100. The first electrode 120 is arranged on a chamber wall, the second electrode 130 is arranged on a chamber ceiling, and the third electrode 140 is arranged on the chamber floor. The arrangement of the electrodes in the chamber can be adjusted as desired to control, among other things, a plasma distribution.

In FIGS. 2 to 9a, the substrate S can be either negatively or positively biased, wherein the positive bias should be less than that of the electrode, as otherwise all the electrons will flow to the substrate. In the operating state, argon (Ar) and hydrogen (H₂) can preferably be supplied as the working gas, and nitrogen (N₂) can preferably be supplied as the process gas.

While various exemplary configurations have been shown and described within the framework of this application, other embodiments with any number of evaporators and any number of electrodes naturally fall within the scope of protection of the invention claimed herein. Furthermore, a vacuum chamber according to the invention can be used for ion etching processes and can be equipped with a plurality of individual electrodes, whereby different electrodes can be supplied with different currents. The same or different currents can be applied to the different electrodes, even at different times, to manipulate the plasma activation and etching as desired.

The electron paths 150, 160, 260 included in the figures are represented only schematically, since the electron paths 150, 160, 260 of course pass by the shields 115, 230, 332, 333, 334 and do not pass through them.

Although quite a number of embodiments have already been described within the framework of the present application, it goes without saying that further variations are possible. For example, the described embodiments may be suitably combined and supplemented or replaced by equivalent features having the same effect. Accordingly, such other solutions also fall within the scope of protection of the claimed invention.

1. A vacuum chamber for performing a plasma treatment comprising a plasma treatment area which is enclosed by chamber walls, and a plasma source comprising:
a cathode for cathodic vacuum arc evaporation with an arc anode which is connected to the chamber, wherein the cathode is arranged in the chamber on the chamber wall;
a shield for shielding particles and metal ions which are emitted from the cathode, wherein the shield is provided in the vacuum chamber in such a way that it can be arranged in front of the cathode;
an electrode arranged in the chamber and spaced from the cathode;
wherein
the electrode comprises a two-dimensional surface for collecting electrons emitted from the cathode, and in that the two-dimensional surface has a first orthogonal extension and a second orthogonal extension to a surface normal, wherein the first orthogonal extension is perpendicular to the second orthogonal extension, wherein a length ratio of the first orthogonal extension to the second orthogonal extension is between 0.1 and 1.

2. The vacuum chamber according to claim 1, wherein the length ratio of the first orthogonal extension to the second orthogonal extension is between 0.2 and 1, in particular between 0.4 and 1, especially at 1 and/or the two-dimensional surface area is in the range between 5 to 2000 cm², in particular 25 to 320 cm², and/or the electrode is arranged at least partially in the chamber wall.

3. The vacuum chamber according to claim 1, wherein the two-dimensional surface has a structuring, wherein a ratio of a maximum depth of the structuring and a smaller orthogonal extension of the two-dimensional surface of the electrode is at most 0.4, and/or the two-dimensional surface of the electrode is angular, round or ellipsoidal.

4. The vacuum chamber according to claim 1, wherein the electrode is provided on a chamber wall comprising the cathode or on another chamber wall, wherein the distance between the cathode and the electrode is in a range between 1 cm to 200 cm, preferably 5 to 150 cm, in particular 10 to 100 cm.

5. The vacuum chamber according to claim 1, wherein a current density of the electrode is between 0.1 to 5 A/cm², in particular between 0.1 to 4 A/cm², especially between 0.2 to 2 A/cm2 and/or a voltage of the electrode is between 5 to 100 V, in particular between 10 to 100 V, especially between 20 to 60 V and/or a power density of the electrode is between 0.25 to 500 W/cm², in particular between 1 to 400 W/cm², especially between 4 to 120 W/cm², and/or a current of the electrode of an area of about 80 cm² is between 5 to 400 A, in particular between 10 to 300 A, especially between 20 to 200 A, particularly preferably between 10 and 150 A.

6. The vacuum chamber according to claim 1, wherein the electrode is designed as a coating source and can be connected to a power supply in such a way that the coating source can be used as an evaporator or as a plasma electrode.

7. The vacuum chamber according to claim 1 comprising a plurality of electrodes and/or a plurality of cathodes, in particular two electrodes and two cathodes, especially three electrodes three cathodes.

8. The vacuum chamber according to claim 7 comprising an equal number of electrodes and cathodes or comprising a larger number of electrodes than cathodes, in particular two electrodes and the one single cathode, especially three electrodes and the one single cathode or comprising a larger number of cathodes than electrodes, in particular two cathodes and the one single electrode, especially three cathodes and the one single electrode.

9. The vacuum chamber according to claim 1, wherein a part of the electrode forming the working surface is a cooled part of the electrode, in particular a water-cooled part of the electrode, and the cooled part of the electrode can in particular be cooled directly or is arranged on a cooling body.

10. The vacuum chamber according to claim 1, wherein the electrode comprises graphite, an alloy of copper carbon, steel, copper, a copper alloy, aluminum, an aluminum alloy, or conductive evaporator materials such as aluminum titanium, chromium, or vanadium, and/or the cathode comprises titanium, a titanium alloy, zirconium, a zirconium alloy, aluminum, an aluminum alloy, or oxygen-gettering materials.
